(19) United States
(12) Patent Application Publication
(10) Pub. No.: US 2026/0031110 A1
(43) Pub. Date: Jan. 29, 2026

(54) MEMORY DEVICE FOR IMPROVING SIGNAL SETUP SPEED OF WORD LINES AND BIT LINES

(71) Applicant: Samsung Electronics Co., Ltd., Suwon-si (KR)

(72) Inventor: Sukhyun Lim, Suwon-si (KR)

(21) Appl. No.: 19/246,968

(22) Filed: Jun. 24, 2025

(30) Foreign Application Priority Data
Jul. 23, 2024 (KR) 10-2024-0097515

(51) Int. Cl. G11C 5/06; G11C 11/408; G11C 11/4091

(52) U.S. Cl. CPC G11C 5/063; G11C 11/4085; G11C 11/4087; G11C 11/4091

(57) ABSTRACT

A memory device includes a core peripheral circuit structure and a cell array structure. The cell array structure includes a first sub-array and a second sub-array. The core peripheral circuit structure includes first and second even sub-word line driver circuit and first and second odd sub-word line driver circuits. A first area of the core peripheral circuit structure at least partially overlaps the first sub-array and includes the first even sub-word line driver circuit and the first odd sub-word line driver circuit. A second area of the core peripheral circuit structure at least partially overlaps the second sub-array and includes the second even sub-word line driver circuit and the second odd sub-word line driver circuit.

### CROSS-REFERENCE TO RELATED APPLICATION

This application is based on and claims priority under 35 U.S.C. § 119 to Korean Patent Application No. 10-2024-0097515, filed on Jul. 23, 2024, in the Korean Intellectual Property Office, the disclosure of which is incorporated by reference herein in its entirety.

### TECHNICAL FIELD

The present disclosure relates to semiconductor memory devices, and more particularly, to memory devices for improving signal setup speeds of word lines and bit lines.

### BACKGROUND

As information communication devices have recently become multifunctional, memory devices may have larger capacity and higher integrity. As sizes of memory cells have decreased for higher integration, operation circuits and/or wiring structures included in memory devices for the operation and electrical connection of memory devices have become more complex. Memory devices with improved integration and excellent electrical characteristics are desired. In order to improve the storage capacity and integration of memory devices, vertical channel transistors vertically formed on semiconductor substrates, rather than planar channel transistors horizontally formed on semiconductor substrates, are being introduced.

A memory device, for example, a dynamic random-access memory (DRAM), includes a plurality of memory cells including a vertical channel transistor and a capacitor, and operates by writing and reading data by using charges stored in the capacitor. The memory cells are connected to word lines and bit lines. In the DRAM, when a read operation or a refresh operation is performed, a row decoder may decode a row address to select a word line corresponding to the row address and may apply a word line driving voltage of a high voltage to the selected word line, and sense amplifiers may sense voltage levels of bit lines corresponding to a column address from among bit lines of memory cells connected to the selected word line.

Signal setup of the word lines and the bit lines is an example consideration for operation timing of the DRAM. A signal setup speed of the word lines and the bit lines may improve the high-speed operation performance of the DRAM.

### SUMMARY

The present disclosure provides memory devices for improving signal setup speeds of word lines and bit lines.

According to an aspect of the present disclosure, a memory device includes a core peripheral circuit structure including a first bonding metal pad, and a cell array structure on the core peripheral circuit structure, the cell array structure including a second bonding metal pad contacting the first bonding metal pad. The cell array structure includes a memory cell array area including a plurality of memory blocks that include a plurality of word lines, each of the plurality of memory blocks including a first sub-array and a second sub-array. The core peripheral circuit structure includes a row decoder including a sub-word line driver circuit that is electrically connected to the first bonding metal pad and the second bonding metal pad and is electrically connected to each of the plurality of word lines of the plurality of memory blocks, the sub-word line driver circuit including a first even sub-word line driver circuit, a second even sub-word line driver circuit, a first odd sub-word line driver circuit, and a second odd sub-word line driver circuit. A first area of the core peripheral circuit structure at least partially overlaps the first sub-array in a first direction, the first area of the core peripheral circuit structure including the first even sub-word line driver circuit that is electrically connected to even word lines of the first sub-array and the first odd sub-word line driver circuit that is electrically connected to odd word lines of the first sub-array. A second area of the core peripheral circuit structure at least partially overlaps the second sub-array in the first direction, the second area of the core peripheral circuit structure including the second even sub-word line driver circuit that is electrically connected to even word lines of the second sub-array and the second odd sub-word line driver circuit that is electrically connected to odd word lines of the second sub-array.

According to another aspect of the present disclosure, a memory device includes a core peripheral circuit structure including a first bonding metal pad and a cell array structure on the core peripheral circuit structure, the cell array structure including a second bonding metal pad contacting the first bonding metal pad. The cell array structure includes a memory cell array area including a plurality of memory blocks that include a plurality of bit lines, each of the plurality of memory blocks including a first sub-array and a second sub-array. The core peripheral circuit structure includes a sense amplifier circuit electrically connected to the first bonding metal pad and the second bonding metal pad and is electrically connected to each of the plurality of bit lines, the sense amplifier circuit including a first even bit line sense amplifier circuit, a second even bit line sense amplifier circuit, a first odd bit line sense amplifier circuit, and a second odd bit line sense amplifier circuit. A first area of the core peripheral circuit structure at least partially overlaps the first sub-array in a first direction, the first area of the core peripheral circuit structure including the first even bit line sense amplifier circuit that is electrically connected to each of even bit lines of the first sub-array and a first odd bit line sense amplifier circuit electrically connected to each of odd bit lines of the first sub-array. A second area of the core peripheral circuit structure at least partially overlaps the second sub-array in the first direction, the second area of the core peripheral circuit structure including the second even bit line sense amplifier circuit that is electrically connected to each of even bit lines of the second sub-array and a second odd bit line sense amplifier circuit electrically connected to each of odd bit lines of the second sub-array.

According to another aspect of the present disclosure, a memory device includes a core peripheral circuit structure including a first bonding metal pad and a cell array structure on the core peripheral circuit structure, the cell array structure including a second bonding metal pad contacting the first bonding metal pad. The cell array structure includes a memory cell array area including a plurality of memory blocks that include a plurality of word lines and a plurality of bit lines, each of the plurality of memory blocks including a first sub-array and a second sub-array. The core peripheral circuit structure includes a row decoder electrically that is electrically connected to the first bonding metal pad and the second bonding metal pad and is electrically connected to each of the plurality of word lines of the plurality of memory blocks, the row decoder including a sub-word line driver circuit of the row decoder connected to each of the first sub-array and the second sub-array, the sub-word line driver circuit including a first even sub-word line driver circuit, a second even sub-word line driver circuit, a first odd sub-word line driver circuit, and a second odd sub-word line driver circuit. The core peripheral circuit structure includes a sense amplifier circuit that is electrically connected to the first bonding metal pad and the second bonding metal pad and is electrically connected to each of the plurality of bit lines of the plurality of memory blocks, the sense amplifier circuit including a first even bit line sense amplifier circuit, a second even bit line sense amplifier circuit, a first odd bit line sense amplifier circuit, and a second odd bit line sense amplifier circuit. A first area of the core peripheral circuit structure at least partially overlaps the first sub-array in a first direction, the first area of the core peripheral circuit structure including the first even bit line sense amplifier circuit electrically connected to each of even bit lines of the first sub-array, the first even sub-word line driver circuit electrically connected to even word lines of the first sub-array, the first odd sub-word line driver circuit electrically connected to odd word lines of the first sub-array, and the first odd bit line sense amplifier circuit electrically connected to each of odd bit lines of the first sub-array. A second area of the core peripheral circuit structure at least partially overlaps the second sub-array in the first direction, the second area of the core peripheral circuit structure including the second even sub-word line driver circuit electrically connected to even word lines of the second sub-array, the second even bit line sense amplifier circuit electrically connected to each of even bit lines of the second sub-array, the second odd bit line sense amplifier circuit electrically connected to each of odd bit lines of the second sub-array, and the second odd sub-word line driver circuit electrically connected to odd word lines of the second sub-array.

### BRIEF DESCRIPTION OF THE DRAWINGS

Embodiments will be more clearly understood from the following detailed description taken in conjunction with the accompanying drawings in which:

FIGS. 1 and 2 are conceptual diagrams illustrating a memory device, according to embodiments;

FIGS. 3A, 3B, 3C, and 3D are diagrams for describing a row decoder of FIG. 1;

FIG. 4 is a diagram for describing a sense amplifier of FIG. 1;

FIGS. 5, 6A, and 6B are diagrams for describing a memory device including sub-word line driver circuits, according to embodiments;

FIGS. 7 and 8 are diagrams for describing a memory device including sub-word line driver circuits and sense amplifier circuits of FIG. 5;

FIGS. 9A and 9B are diagrams for describing a memory device including sense amplifier circuits, according to embodiments;

FIGS. 10A, 10B, and 11 are diagrams for describing a structure of a memory device, according to embodiments; and

FIG. 12 is a block diagram illustrating a system for describing an electronic device including a memory device, according to embodiments.

### DETAILED DESCRIPTION

To clarify the present disclosure, the same elements or equivalents are referred to by the same reference numerals throughout the specification. Further, since sizes and thicknesses of constituent members shown in the accompanying drawings are arbitrarily given for better understanding and ease of description, the present disclosure is not limited to the illustrated sizes and thicknesses. In the drawings, the thickness of layers, films, panels, regions, etc., are exaggerated for clarity. In the drawings, for better understanding and ease of description, thicknesses of some layers and areas are excessively displayed.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, spatially relative terms, such as “beneath,” “below,” “lower,” “above,” “upper,” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations), and the spatially relative descriptors used herein may be interpreted accordingly.

In addition, unless explicitly described to the contrary, the word “comprises”, and variations such as “comprises” or “comprising”, will be understood to imply the inclusion of stated elements but not the exclusion of any other elements. As used herein, the singular forms “a,” “an” and “the” are intended to include the plural forms as well, unless the context clearly indicates otherwise. The term “and/or” includes any and all combinations of one or more of the associated listed items. The term “connected” may be used herein to refer to a physical and/or electrical connection and may refer to a direct or indirect physical and/or electrical connection. The term “exposed” may be used to define a relationship between particular layers or surfaces, but it does not require the layer or surface to be free of other elements or layers thereon in the completed device. Components or layers described with reference to “overlap” in a particular direction may be at least partially obstructed by one another when viewed along a line extending in the particular direction or in a plane perpendicular to the particular direction.

A memory device described in the present disclosure may be a dynamic random-access memory (DRAM) having a cell over periphery (COP) structure including a cell array structure and a core peripheral circuit structure vertically overlapping each other. The cell array structure may include a memory cell array including a plurality of memory cells including a vertical channel transistor and a capacitor, and the core peripheral circuit structure may include peripheral circuits including a row decoder and a sense amplifier. The row decoder may decode a row address to select a word line corresponding to the row address and may apply a word line driving voltage of a high voltage to the selected word line. The sense amplifier may sense voltage levels of bit lines corresponding to a column address from among bit lines of memory cells connected to the selected word line. The memory cell array may include a plurality of memory blocks (sometimes called memory banks), and each of the memory blocks may be divided into logical and/or physical groups in terms of addressing/memory access by a memory controller and divided into sub-arrays. Word lines and/or bit lines of each of the sub-arrays may have a slow signal setup speed due to various factors (e.g., load). The slow signal setup speed reduces a timing margin of operations (e.g., write and read) of the memory device and reduces data reliability. Hereinafter, a memory device for improving an improved signal setup speed of word lines and bit lines connected to sub-arrays and improving high-speed operation performance is provided.

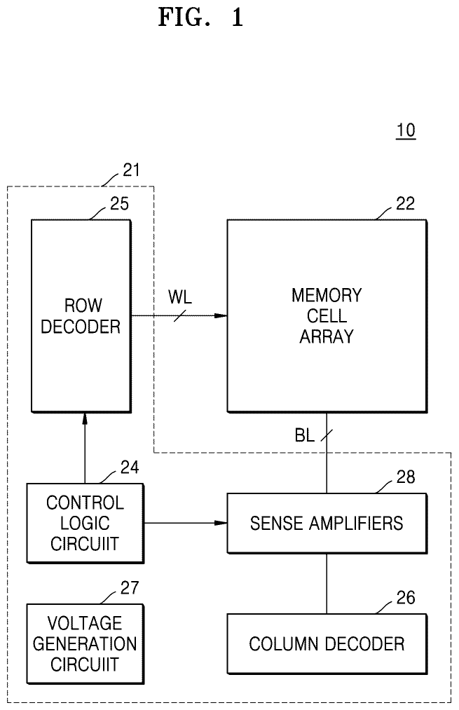

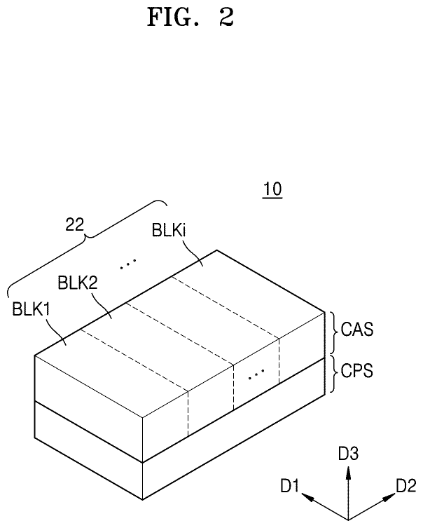

FIGS. 1 and 2 are conceptual diagrams illustrating a memory device, according to embodiments. FIG. 2 is a diagram for describing a semiconductor structure of a memory device 10 of FIG. 1. For convenience of understanding, the terms ‘top/bottom, upper/lower, up/down, and left/right’ are based on directions illustrated in referenced drawings. Accordingly, even the same surface may be referred to as a top surface and a bottom surface according to directions illustrated in the drawings.

Referring to FIG. 1, the memory device 10 may include a core peripheral circuit 21 and a memory cell array 22, and the core peripheral circuit 21 may include a control logic circuit 24, a row decoder 25, a column decoder 26, a voltage generation circuit 27, and a sense amplifier 28. The core peripheral circuit 21 may further include a common address circuit, an input/output gating circuit, and a data input/output circuit. In embodiments, the memory device 10 may be a DRAM including a plurality of memory cells including a vertical channel transistor and a capacitor, and hereinafter, a “memory device” refers to a DRAM.

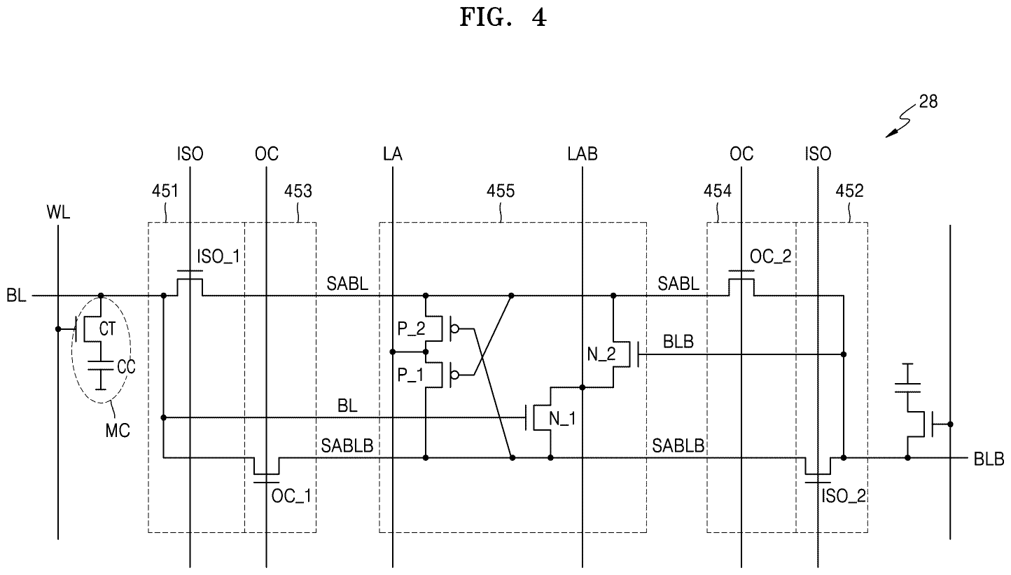

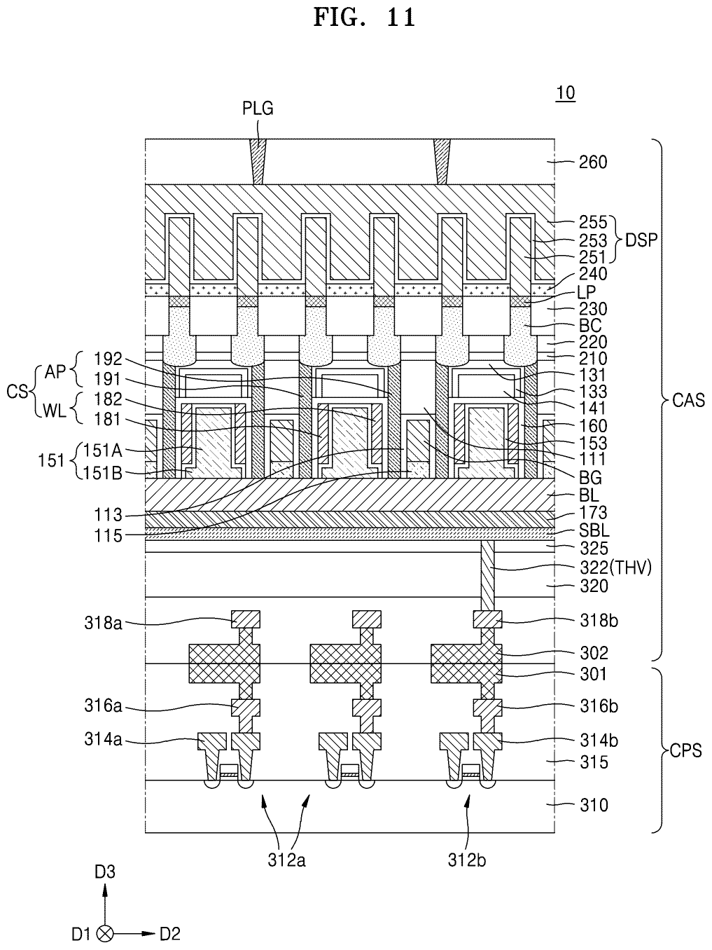

The memory cell array 22 may be connected to the row decoder 25 through word lines WL, and may be connected to the sense amplifier 28 through bit lines BL. The memory cell array 22 may include a plurality of word lines WL, a plurality of bit lines BL, and a plurality of memory cells formed at intersections between the word lines WL and the bit lines BL, and may be divided into a plurality of memory blocks (e.g., BLK1 to BLKi) (i is an integer equal to or greater than 2) (see FIG. 2). The memory cell array 22 includes the plurality of word lines WL and the plurality of bit lines BL connected to memory cells MC (see FIG. 4). Each of the memory cells MC may include a cell transistor CT and a cell capacitor CC, and the cell transistor CT may be implemented as a cell structure CS described with reference to FIG. 11 and the cell capacitor CC may be implemented as a capacitor structure DSP. A gate of the cell transistor CT is connected to one of the plurality of word lines WL. One end of the cell transistor CT is connected to one of the plurality of bit lines BL. The cell capacitor CC may store charges corresponding to single-bit data or multi-bit data.

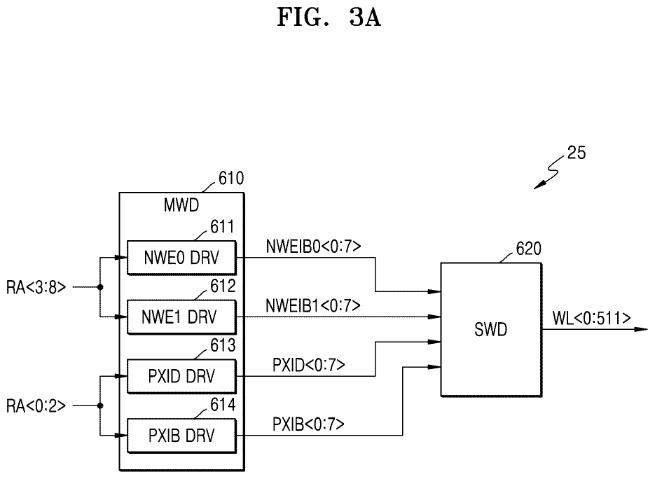

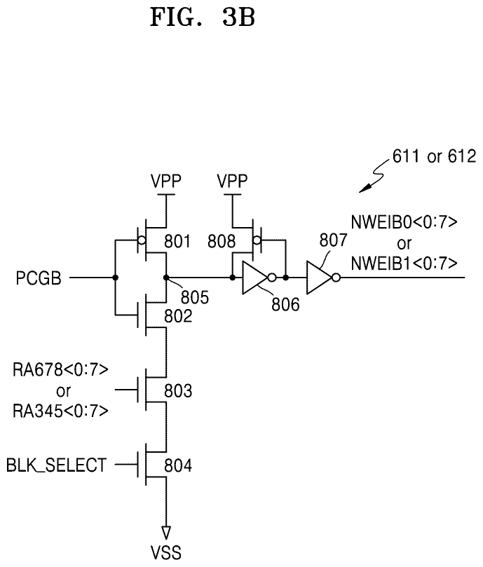

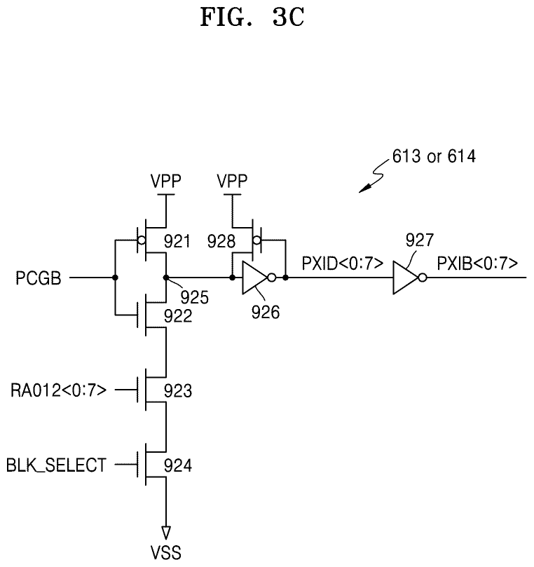

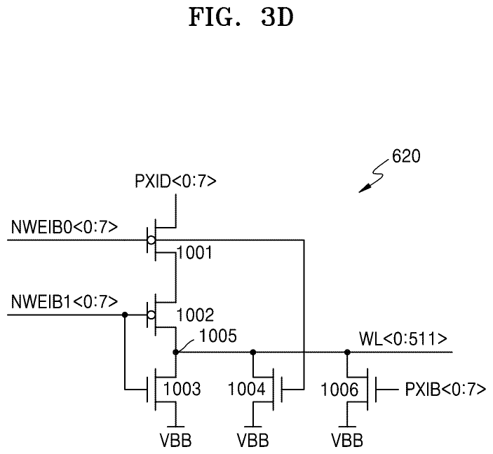

The voltage generation circuit 27 may generate various internal voltages for driving circuits of the memory device 10. The voltage generation circuit 27 may generate a high voltage VPP, a negative voltage VBB, an internal power supply voltage, a bit line precharge voltage, a reference voltage, and a bulk bias voltage by using a power supply voltage VDD applied from the outside of the memory device 10. For example, the high voltage VPP is provided to the row decoder 25, has a higher voltage level than the power supply voltage VDD, and may be used for main word line driving signal generation circuits (see FIGS. 3A, 3B, and 3C) and sub-word line driving signal generation circuits (see FIGS. 3A and 3D) to turn on an N-type metal oxide semiconductor (NMOS) cell transistor connected to the word lines WL. The negative voltage VBB has a lower negative (−) voltage level than the power supply voltage VDD, and may be used to increase a data retention time by increasing a threshold voltage Vth of an NMOS transistor. The negative voltage VBB may be applied to a well region where the NMOS transistor is formed and may be referred to as a bulk bias voltage or a back bias voltage. The bit line precharge voltage may be used to equalize the bit line BL and a complementary bit line before the sense amplifier 28 senses a voltage difference between the bit line BL and the complementary bit line. The internal power supply voltage may be provided to first and second sensing driving voltage lines LA and LAB (see FIG. 4) of the sense amplifier 28. The sense amplifier 28 may detect and amplify a voltage difference between the bit line BL and the complementary bit line according to the first and second sensing driving voltage lines LA and LAB. The reference voltage may be used for comparison with a voltage of a signal received from a command/address bus to determine a logical value of a signal received from a memory controller.

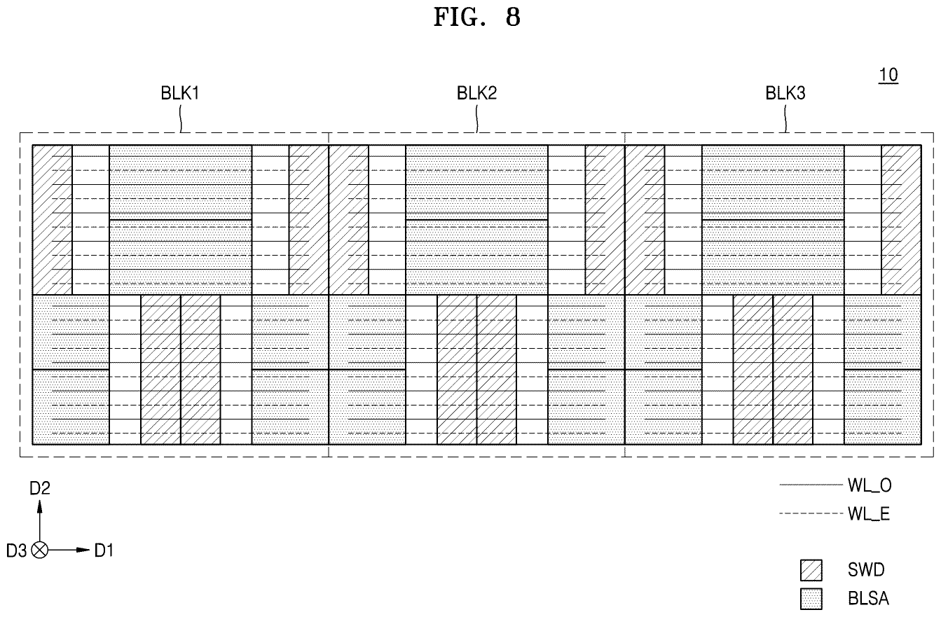

A command address circuit may receive a command and an address received together with the command from the memory controller connected to the memory device 10, and may capture a block selection signal for selecting a memory block where the command is to be performed, a row address (e.g., RA<0:8>) (see FIG. 8), and a column address. The command address circuit may provide the received row address RA<0:8> to the row decoder 25 and may provide the received column address to the column decoder 26.

The control logic circuit 24 may control overall operations of the memory device 10. The control logic circuit 24 may generate control signals to perform a write operation and/or a read operation of the memory device 10. The control logic circuit 24 may include a mode register for setting a plurality of operation options and a command decoder for decoding the command received from the memory controller.

The sense amplifier 28 may sense data stored in a memory cell and may transmit the sensed data to the data input/output circuit to output the data to the memory controller through a data pad (or data pads). The data input/output circuit may receive data to be written to memory cells from the memory controller through the data pad(s) and may transmit the data to the memory cell array 22. The input/output gating circuit may output read data by using a data line amplifier for receiving and amplifying data sensed by the sense amplifier 28. The read data may be output to the memory controller through the data pad(s). The input/output gating circuit may include a column selection circuit, an input data mask logic, read data latches, and/or a write driver together with circuits for gating input/output data.

In some embodiments, read data output from one of the plurality of memory blocks (e.g., BLK1 to BLKi) may be detected by the sense amplifier 28 and may be stored in the read data latches. Write data to be written to one of the plurality of memory blocks (e.g., BLK1 to BLKi) may be provided from the memory controller to the data input/output circuit. The data provided to the data input/output circuit may be written to one memory block through the write driver.

Referring to FIG. 2, the memory device 10 may include a cell array structure CAS and a core peripheral circuit structure CPS overlapping each other in a vertical direction (D3 direction). The cell array structure CAS may include the memory cell array 22 of FIG. 1, and the core peripheral circuit structure CPS may include the core peripheral circuit 21 of FIG. 1.

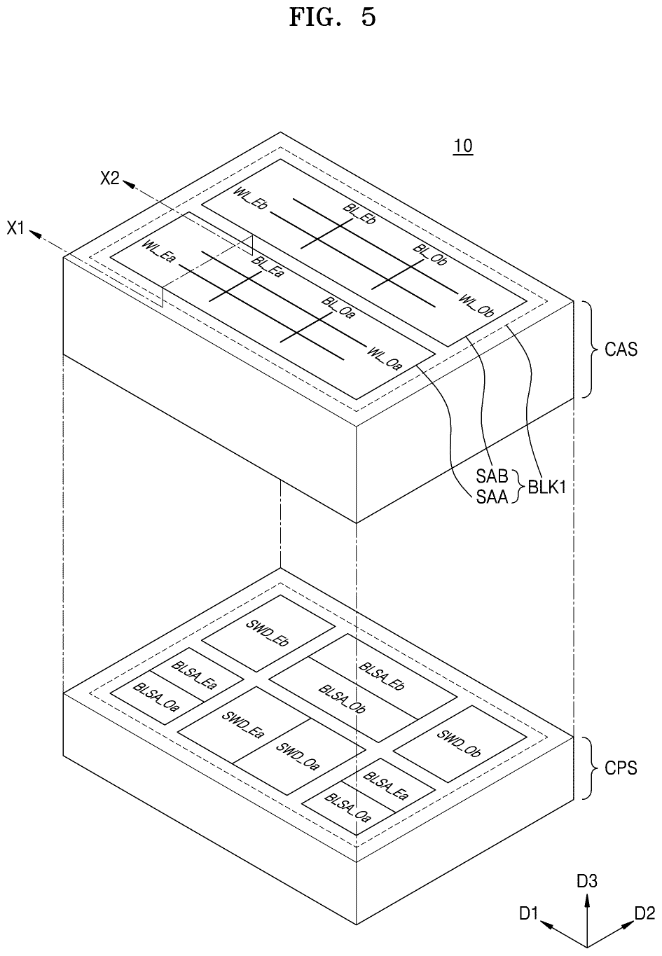

The cell array structure CAS may include the plurality of memory blocks (e.g., BLK1, BLK2, . . . , and BLKi) (i is a positive integer). The plurality of memory blocks (e.g., BLK1, BLK2, . . . , and BLKi) may include a plurality of memory cells including a vertical channel transistor and a capacitor. The core peripheral circuit structure CPS may include a semiconductor substrate, and the core peripheral circuit 21 may be formed by forming semiconductor devices such as a transistor and a pattern for wiring the devices on the semiconductor substrate. The core peripheral circuit 21 may be formed in the core peripheral circuit structure CPS and then the cell array structure CAS including the memory cell array 22 may be formed, and patterns (e.g., bonding metal pads 301 and 302 of FIG. 11) for electrically connecting the word lines WL and the bit lines BL of the memory cell array 22 to a core peripheral circuit formed in the core peripheral circuit structure CPS may be formed. The cell array structure CAS and the core peripheral circuit structure CPS will be described in detail with reference to FIGS. 5 to 11.

FIGS. 3A, 3B, 3C, and 3D are diagrams for describing a row decoder of FIG. 1. FIG. 3A is a block diagram for describing the row decoder 25 of FIG. 1. FIGS. 3B and 3C are circuit diagrams for describing a main word line driver circuit 610 of FIG. 3A. FIG. 3D is a circuit diagram for describing a sub-word line driver circuit 620 of FIG. 3A.

Referring to FIG. 3A, the row decoder 25 may select a word line WL corresponding to a row address RA for one of the plurality of memory blocks (e.g., BLK1 to BLKi). The row decoder 25 may decode the row address RA to select any one of the plurality of memory blocks (e.g., BLK1 to BLKi) and may select a word line WL of the selected memory block. The row decoder 25 may include the main word line driver circuit 610 and the sub-word line driver circuit 620 Although each of the memory blocks (e.g., BLK1 to BLKi) includes 512 word lines according to 9 row address (RA<0:8>) signal configurations in the present embodiments, the present disclosure is not limited thereto and each of the memory blocks (e.g., BLK1 to BLKi) may include various numbers of word lines. For example, each of the memory blocks (e.g., BLK1 to BLKi) may include 1024 or 2048 word lines WL according to 10 row address (RA<0:9>) or 11 row address (RA<0:10>) signal configurations.

In some embodiments, each of the memory blocks (e.g., BLK1 to BLKi) may include two sub-arrays (e.g., SAA and SAB) (see FIG. 5). The main word line driver circuit 610 may be commonly connected to the sub-arrays (e.g., SAA and SAB), and the sub-word line driver circuit 620 may be connected to each of the sub-arrays (e.g., SAA and SAB). The description of operations of sub-arrays (e.g., SAA and SAB) of a first memory block BLK1 may apply to the remaining memory blocks (e.g., BLK2 to BLKi). Hereinafter, a memory block refers to the first memory block BLK1.

The main word line driver circuit 610 may include first and second main word line driving signal generation circuits 611 and 612 and first and second sub-word line driving signal generation circuits 613 and 614. The main word line driver circuit 610 may generate first and second main word line driving signals NWEIB0<0:7> and NWEIB1<0:7> based on most significant bit (MSB) group signals from among row address (RA<0:8>) signals. The MSB group signals from among the row address (RA<0:8>) signals may be set to an RA<3:8> row address. The RA<3:8> row address may be divided into an RA<6:8> row address that is an upper bit group (hereinafter, referred to as “RA678”) and an RA<3:5> row address that is a lower bit group (hereinafter, referred to as “RA345”).

In some embodiments, the first main word line driving signal generation circuit 611 may generate the first main word line driving signal NWEIB0<0:7> by decoding the RA678 row address, and the second main word line driving signal generation circuit 612 may generate the second main word line driving signal NWEIB1<0:7> by decoding the RA345 row address. The main word line driving circuit 610 of the present embodiments divides MSB signals RA<3:8> of the row address (RA<0:8>) signals into 2 groups (e.g., RA678 and RA345) and generates 8 first and second main word line driving signals NWEIB0<0:7> and NWEIB1<0:7> based on the 2 groups. In some embodiments, the main word line driver circuit 610 may change decoding for generating a plurality of main word line driving signals NWEIBn−1 (n is a natural number) based on the number of bits (e.g., 5, 6, or 7) of MSB group signals of row address signals according to various numbers of word lines (e.g., 1024 or 2048).

Referring to FIG. 3B, the first main word line driving signal generation circuit 611 may include first to fourth transistors 801 to 804 connected in series between a high voltage (VPP) line and a ground voltage (VSS) line, may include first and second inverters 806 and 807 connected in series to a connection node 805 of the first and second transistors 801 and 802, and may include a firth transistor 808 connected between the high voltage (VPP) line and the connection node 805 of the first and second transistors 801 and 802. The first to fourth transistors 801 to 804 may constitute a NAND logic circuit. The first transistor 801 may be a P-type metal oxide semiconductor (PMOS) transistor including a gate to which a precharge signal PCGB is connected, and the second transistor 802 may be an NMOS transistor including a gate to which the precharge signal PCGB is connected.

In some embodiments, the precharge signal PCGB is provided based on a precharge command by the control logic circuit 24, and may serve as a signal for activating the row decoder 25. The row decoder 25 may be activated by the precharge signal PCGB of a logic high level, and the row decoder 25 may be deactivated by the precharge signal PCGB of a logic low level.

The third transistor 803 may be an NMOS transistor including a gate to which a decoded RA678<0:7> row address signal is connected, and the fourth transistor 804 may be an NMOS transistor including a gate to which a block selection signal BLK_SELECT is connected. The block selection signal BLK_SELECT may be provided to select one memory block from among the plurality of memory blocks (e.g., BLK1 to BLKi). For example, a first block selection signal of a logic high level may be provided to select the first memory block BLK1.

The first and second inverters 806 and 807 connected in series to the connection node 805 of the first and second transistors 801 and 802 may output the first main word line driving signal NWEIB0<0:7>. The fifth transistor 808 may be a PMOS transistor including a gate to which an output of the first inverter 806 is connected, and may be referred to as a keeper transistor for stably maintaining the output of the first inverter 806.

There may be 8 first main word line driving signal generation circuits 611 each outputting the first main word line driving signal NWEIB0<0:7> in response to the decoded RA678<0:7> row address signal. Because there are 8 configurations of the decoded RA678<0:7> row address signal (i.e., 000, 001, 010, 011, 100, 101, 110, and 111), there may be 8 configurations of the first main word line driving signal NWEIB0<0:7> to be activated. That is, according to the decoded RA678<0:7> row address signal, any one of NWEIB0<0>, NWEIB0<1>, NWEIB0<2>, NWEIB0<3>, NWEIB0<4>, NWEIB0<5>, NWEIB0<6>, and NWEIB0<7> may be activated to a logic low level. The first main word line driving signal NWEIB0<0:7> of a logic low level may have a ground voltage (VSS) level, and may be provided to the sub-word line driver circuit 620 connected to the memory block BLK1.

There may be 8 second main word line driving signal generation circuits 612 each outputting the second main word line driving signal NWEIB1<0:7> in response to a decoded RA345<0:7> row address signal. Because there are 8 configurations of the decoded RA345<0:7> row address signal (i.e., 000, 001, 010, 011, 100, 101, 110, and 111), there may be 8 configurations of the second main word line driving signal NWEIB1<0:7> to be activated. That is, according to the decoded RA345<0:7> row address signal, any one of NWEIB1<0>, NWEIB1<1>, NWEIB1<2>, NWEIB1<3>, NWEIB1<4>, NWEIB1<5>, NWEIB1<6>, and NWEIB1<7> may be activated to a logic low level. The second main word line driving signal NWEIB1<0:7> of a logic low level may have a ground voltage (VSS) level, and may be provided to the sub-word line driver circuit 620 connected to the memory block BLK1.

The main word line driver circuit 610 of FIG. 3A may generate first and second sub-word line driving signals PXID<0:7> and PXIB<0:7> based on least significant bit (LSB) group signals from among the row address (RA<0:8>) signals. The LSB group signals from among the row address (RA<0:8>) signals may be set to an RA<0:2> row address (hereinafter, referred to as “RA012”). The main word line driver circuit 610 may include the first sub-word line driving signal generation circuit 613 that generates the first sub-word line driving signal PXID<0:7> by decoding the RA012 row address, and the second sub-word line driving signal generation circuit 614 that generates the second sub-word line driving signal PXIB<0:3> by decoding the RA012 row address.

Although the main word line driver circuit 610 of the present embodiments generates 8 first and second sub-word line driving signals PXID<0:3> and PXIB<0:3> based on LSB signals RA<0:2> of the row address (RA<0:8>) signals, this is only an example to help understanding and is not intended to limit the present disclosure. In other embodiments, the main word line driver circuit 610 may change decoding for generating a plurality of sub-word line driving signals PXIDj and PXIBk (where j and k are natural numbers) based on the number of bits (e.g., 3, 4, or 5) of LSB group signals of row address signals according to various numbers of word lines (e.g., 1024 or 2048).

Referring to FIG. 3C, the first sub-word line driving signal generation circuit 613 may include first to fourth transistors 921 to 924 connected in series between a high voltage (VPP) line and a ground voltage (VSS) line, may include first and second inverters 926 and 927 connected in series to a connection mode 925 of the first and second transistors 921 and 922, and may include a fifth transistor 928 connected between the high voltage (VPP) line and the connection node 925 of the first and second transistors 921 and 922. The first to fourth transistors 921 and 924 may constitute a NAND logic circuit. The first transistor 921 may be a PMOS transistor including a gate to which a precharge signal PCGB is connected, and the second transistor 922 may be an NMOS transistor including a gate to which the precharge signal PCGB is connected. The third transistor 923 may be an NMOS transistor including a gate to which a decoded RA012<0:7> row address signal is connected, and the fourth transistor 924 may be an NMOS transistor including a gate to which a block selection signal BLK_SELECT is connected. The inverter 926 may output the first sub-word line driving signal PXID<0:7>. The fifth transistor 928 may be a PMOS transistor including a gate to which an output of the inverter 926 is connected, and may be referred to as a keeper transistor for stably maintaining the output of the inverter 926.

There may be 8 first sub-word line driving signal generation circuits 613 each outputting a first sub-word line driving signal PXID<0:7> in response to the decoded RA012<0:7> row address signal. Because there are 8 configurations of the decoded RA012<0:7> row address signal (i.e., 000, 001, 010, 011, 100, 101, 110, and 111), there are 8 configurations of the first sub-word line driving signal PXID<0:7> to be activated. That is, according to the decoded RA012<0:7> row address signal, any one of PXID<0>, PIXD<1>, PIXD<2>, PXID<3>, PIXD<4>, PIXD<5>, PXID<6>, and PXID<7> signals may be activated to a logic high level.

The first sub-word line driving signal PXID<0:7> of a logic high level may have a high voltage (VPP) level, and may be provided to the sub-word line driver circuit 620 connected to the memory block BLK1.

There may be 8 second sub-word line driving signal generation circuits 614 each outputting the second sub-word line driving signal PXIB<0:7> in response to the decoded RA012<0:7> row address signal. Because there are 8 configurations of the decoded RA012<0:7> row address signal (i.e., 000, 001, 010, 011, 100, 101, 110, and 111), there are 8 configurations of the second sub-word line driving signals PXIB<0:7> to be activated. That is, according to the decoded RA012<0:7> row address signal, any one of PXIB<0>, PIXB<1>, PIXB<2>, PXIB<3>, PIXB<4>, PIXB<5>, PXIB<6>, and PXIB<7> signals may be activated to a logic low level. The second sub-word line driving signal PXIB<0:7> of a logic low level may have a ground voltage (VSS) level, and may be provided to the sub-word line driver circuit 620 connected to the memory block BLK1.

Referring to FIG. 3D, the sub-word line driver circuit 620 may include first to fifth transistors 1001, 1002, 1003, 1004, and 1006. The first and second transistors 1001 and 1002 may be connected in series between a first sub-word line driving signal (PXID<0:7>) line and a connection node 1005 of the second to fourth transistors 1002 to 1004, the first main word line driving signal NWEIB0<0:7> may be connected to a gate of the first transistor 1001, and the second main word line driving signal NWEIB1<0:7> may be connected to a gate of the second transistor 1002. The third and fourth transistors 1003 and 1004 may be connected in parallel between the connection node 1005 of the second to fourth transistors 1002 to 1004 and a negative voltage (VBB) line, the second main word line driving signal NWEIB1<0:7> may be connected to a gate of the third transistor 1003, and the first main word line driving signal NWEIB0<0:7> may be connected to a gate of the fourth transistor 1004. The fifth transistor 1006 may be an NMOS transistor including a source to which the negative voltage (VBB) line is connected, a drain to which the connection node 1005 of the second to fourth transistors 1002 to 1004 is connected, and a gate to which the second sub-word line driving signal PXIB<0:7> is applied. The connection node 1005 of the second to fourth transistors 1002 to 1004 may be connected to a word line WL<0:511> of the memory blocks (e.g., BLK1 to BLKi). The first to fourth transistors 1001 to 1004 of the sub-word line driver circuit 620 may be implemented as a NOR logic circuit.

There may be 512 sub-word line driver circuits 620 each connected to the word line WL<0:511> in response to the first main word line driving signal NWEIB0<0:7>, the second main word line driving signal NWEIB1<0:7>, the first sub-word line driving signal PXID<0:7>, and the second sub-word line driving signal PXIB<0:7>. The sub-word line driver circuit 620 may select any one of the 512 word lines WL<0:511> and activate the word line to a logic high level in response to a logic low level of the first main word line driving signal NWEIB0<0:7> to be activated, a logic low level of the second main word line driving signal NWEIB1<0:7> to be activated, a logic high level of the first sub-word line driving signal PXID<0:7> to be activated, and a logic low level of the second sub-word line driving signal PXIB<0:8> to be activated. The word line selected from among the word lines WL<0:511> may be activated to a high voltage (VPP) level of the first sub-word line driving signal PXID<0:7> of a logic high level.

In some embodiments, the memory block BLK1 may include a first sub-array SAA and a second sub-array SAB. WL<0:255> word lines from among 512 word lines WL<0:511> of the memory block BLK may be included in the first sub-array SAA, and WL<256:511> word lines may be included in the second sub-array SAB. Accordingly, the sub-word line driver circuit 620 may be divided into first even and odd sub-word line driver circuits SWD_Ea and SWD_Oa (see FIG. 5) that select one of the WL<0:255> word lines of the first sub-array SAA, and second even and odd sub-word line driver circuits SWD_Eb and SWD_Ob (see FIG. 5) that select one of the WL<256:511> word lines of the second sub-array SAB.

FIG. 4 is a diagram for describing the sense amplifier 28 of FIG. 1.

Referring to FIG. 4, the sense amplifier 28 may include first and second isolation units 451 and 452, first and second offset removal units 453 and 454, and a sense amplifier 455. The first isolation unit 451 is connected between a bit line BL and a sensing bit line SABL, and the second isolation unit 452 is connected between a complementary bit line BLB and a complementary sensing bit line SABLB. The first and second isolation units 451 and 452 receive an isolation signal ISO and operate in response to the isolation signal ISO.

The first isolation unit 451 may include a first isolation transistor ISO_1 configured to connect or disconnect the bit line BL to or from the sensing bit line SABL in response to the isolation signal ISO. One end of the first isolation transistor ISO_1 is connected to the bit line BL, the other end of the first isolation transistor ISO_1 is connected to the sensing bit line SABL, and a gate of the first isolation transistor ISO_1 is connected to the isolation signal ISO. The second isolation unit 452 may include a second isolation transistor ISO_2 configured to connect or disconnect the complementary bit line BLB to or from the complementary sensing bit line SABLB in response to the isolation signal ISO. One end of the second isolation transistor ISO_2 is connected to the complementary bit line BLB, the other end of the second isolation transistor ISO_2 is connected to the complementary sensing bit line SABLB, and a gate of the second isolation transistor ISO_2 is connected to the isolation signal ISO.

The first offset removal unit 453 is connected between the bit line BL and the complementary sensing bit line SABLB, and the second offset removal unit 454 is connected between the complementary bit line BLB and the sensing bit line SABL. The first and second offset removal units 453 and 454 receive an offset removal signal OC and operate in response to the offset removal signal OC. The first offset removal unit 453 may include a first offset removing transistor OC_1 configured to connect or disconnect the bit line BL to or from the complementary sensing bit line SABLB in response to the offset removal signal OC. One end of the first offset removing transistor OC_1 is connected to the bit line BL, the other end of the first offset removing transistor OC_1 is connected to the complementary sensing bit line SABLB, and a gate of the first offset removing transistor OC_1 is connected to the offset removal signal OC. The second offset removal unit 454 may include a second offset removing transistor OC_2 configured to connect or disconnect the complementary bit line BLB to or from the sensing bit line SABL in response to the offset removal signal OC. One end of the second offset removing transistor OC_2 is connected to the complementary bit line BLB, the other end of the second offset removing transistor OC_2 is connected to the sensing bit line SABL, and a gate of the second offset removing transistor OC_2 is connected to the offset removal signal OC.

The sense amplifier 455 may be connected between the sensing bit line SABL and the complementary sensing bit line SABLB, and may detect and amplify a voltage difference between the bit line BL and the complementary bit line BLB according to first and second control signals LA and LAB. The sense amplifier 455 includes first and second PMOS transistors P_1 and P_2 and first and second NMOS transistors N_1 and N_2. One end of the first PMOS transistor P_1 is connected to the complementary sensing bit line SABLB, the other end of the first PMOS transistor P_1 is connected to a line of the first control signal LA, and a gate of the first PMOS transistor P_1 is connected to the sensing bit line SABL. One end of the second PMOS transistor P_2 is connected to the sensing bit line SABL, the other end of the second PMOS transistor P_2 is connected to a line of the first control signal LA, and a gate of the second PMOS transistor P_2 is connected to the complementary sensing bit line SABLB. One end of the first NMOS transistor N_1 is connected to the sensing bit line SABLB, the other end of the first NMOS transistor N_1 is connected to a line of the second control signal LAB, and a gate of the first NMOS transistor N_1 is connected to the bit line BL. One end of the second NMOS transistor N_2 is connected to the sensing bit line SABL, the other end is connected to a line of the second control signal LAB, and a gate is connected to the complementary bit line BLB.

In some embodiments, the memory block LBK1 may include the first sub-array SAA and the second sub-array SAB. Bit lines of the memory block BLK may be divided into bit lines of the first sub-array SAA and bit lines of the second sub-array SAB. Accordingly, the bit lines of the first sub-array SAA may be connected to first even and odd bit line sense amplifier circuits BLSA_Ea and BLSA_Oa (see FIG. 5), and the bit lines of the second sub-array SAB may be connected to second even and odd sense amplifier circuits BLSA_Eb and BLSA_Ob (see FIG. 5).

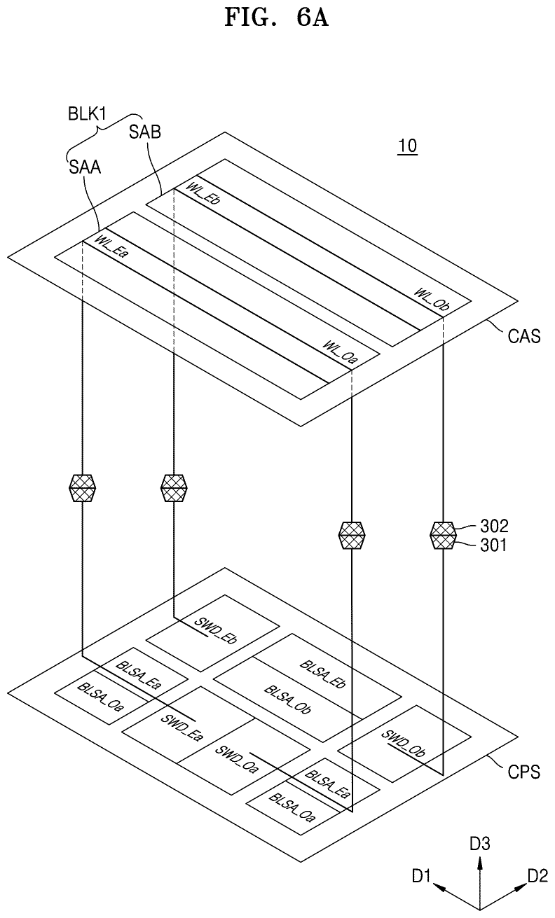

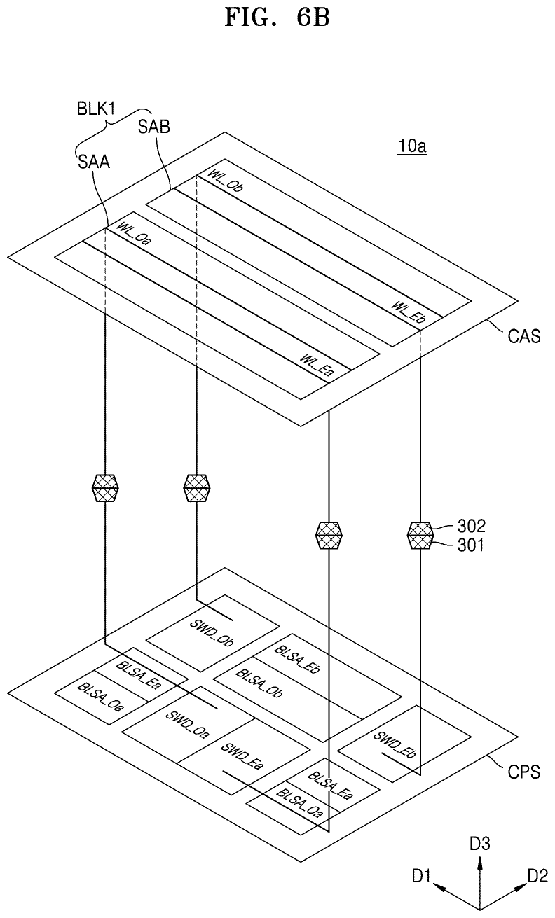

FIGS. 5, 6A, and 6B are diagrams for describing a memory device including sub-word line driver circuits, according to embodiments. Hereinafter, subscripts attached to the same reference number in different drawings (e.g., a of 10a and b of 10b) in different drawings are intended to distinguish multiple components having similar or identical functions. The description of memory devices 10a and 10b which is the same as that of the memory device 10 will be omitted.

Referring to FIG. 5 in connection with FIGS. 3D and 4, the memory device 10 may include the cell array structure CAS and the core peripheral circuit structure CPS overlapping each other in a third direction D3. The cell array structure CAS may include the memory block BLK1 divided into the first sub-array SAA and the second sub-array SAB.

Word lines of the first sub-array SAA may be divided into even-numbered even word lines WL_Ea and odd-numbered odd word lines WL_Oa. For example, from among WL<0:255> word lines of the first sub-array SAA, WL0, WL2, . . . , and WL254 word lines belong to the even word lines WL_Ea, and WL1, WL3, . . . , and WL255 belong to the odd word lines WL_Oa. The first sub-array SAA may include even-numbered even bit lines BL_Ea and odd-numbered odd bit lines BL_Oa.

Word lines of the second sub-array SAB may be divided into even-numbered even word lines WL_Eb and odd-numbered odd word lines WL_Ob. For example, from among WL<256:511> word lines of the second sub-array SAA, WL256, WL258, . . . , and WL510 word lines belong to the even word lines WL_Eb, and WL257, WL259, . . . , and WL511 word lines belong to the odd word lines WL_Ob. The second sub-array SAB may include even-numbered even bit lines BL_Eb and odd-numbered odd bit lines BL_Ob.

The core peripheral circuit structure CPS may include, in an area overlapping the memory block BLK, the first even bit line sense amplifier circuit BLSA_Ea, the first even sub-word line driver circuit SWD_Ea, the first odd sub-word line driver circuit SWD_Oa, and the first odd bit line sense amplifier circuit BLSA_Oa corresponding to the first sub-array SAA, and may include the second even sub-word line driver circuit SWD_Eb, the second even bit line sense amplifier circuit BLSA_Eb, the second odd bit line sense amplifier circuit BLSA_Ob, and the second odd sub-word line driver circuit SWD_Ob corresponding to the second sub-array SAB.

Referring to FIGS. 5 and 6A, the even word lines WL_Ea of the first sub-array SAA may be electrically connected to the first even sub-word line driver circuit SWD_Ea through a bonding metal pad 302 of the cell array structure CAS and the bonding metal pad 301 of the core peripheral circuit structure CPS at a first edge on a left side of the first sub-array SAA. The odd word lines WL_Oa of the first sub-array SAA may be electrically connected to the first odd sub-word line driver circuit SWD_Oa through the bonding metal pads 302 and 301 at a second edge on a right side of the first sub-array SAA. The even word lines WL_Eb of the second sub-array SAB may be electrically connected to the second even sub-word line driver circuit SWD_Eb through the bonding metal pads 302 and 301 at a first edge of the second sub-array SAB. The odd word lines WL_Ob of the second sub-array SAB may be electrically connected to the second odd sub-word line driver circuit SWD_Ob through the bonding metal pads 302 and 301 at a second edge of the second sub-array SAB.

In the present embodiments, the even word lines WL_Ea of the first sub-array SAA may be driven by the first even sub-word line driver circuit SWD_Ea, and the odd word lines WL_Oa may be driven by the first odd sub-word line driver circuit SWD_Oa. As the word lines WL of the first sub-array SAA are driven by the first even sub-word line driver circuit SWD_Ea and the first odd sub-word line driver circuit SWD_Oa at both edges of the first sub-array SAA, a signal setup speed of the word lines WL of the first sub-array SAA may be improved.

Likewise, the even word lines WL_Eb of the second sub-array SAB may be driven by the second even sub-word line driver circuit SWD_Eb, and the odd word lines WL_Ob may be driven by the second odd sub-word line driver circuit SWD_Ob. As the word lines WL of the second sub-array SAB are driven by the second even sub-word line driver circuit SWD_Eb and the second odd sub-word line driver circuit SWD_Ob at both edges of the second sub-array SAB, a signal setup speed of the word lines WL of the second sub-array SAB may be improved.

Referring to FIG. 6B, the memory device 10a is different from the memory device 10 of FIG. 6A in that positions of the first even sub-word line driver circuit SWD_Ea and the first odd sub-word line driver circuit SWD_Oa are exchanged, and positions of the second even sub-word line driver circuit SWD_Eb and the second odd sub-word line driver circuit SWD_Ob are exchanged. That is, the even word lines WL_Ea of the first sub-array SAA may be electrically connected to the first even sub-word line driver circuit SWD_Ea through the bonding metal pads 302 and 301 at a second edge of the first sub-array SAA. The odd word lines WL_Oa of the first sub-array SAA may be electrically connected to the first odd sub-word line driver circuit SWD_Oa through the bonding metal pads 302 and 301 at a first edge of the first sub-array SAA. The even word lines WL_Eb of the second sub-array SAB may be electrically connected to the second even sub-word line driver circuit SWD_Eb through the bonding metal pads 302 and 301 at a second edge of the second sub-array SAB. The odd word lines WL_Ob of the second sub-array SAB may be electrically connected to the second odd sub-word line driver circuit SWD_Ob through the bonding metal pads 302 and 301 at a first edge of the second sub-array SAB.

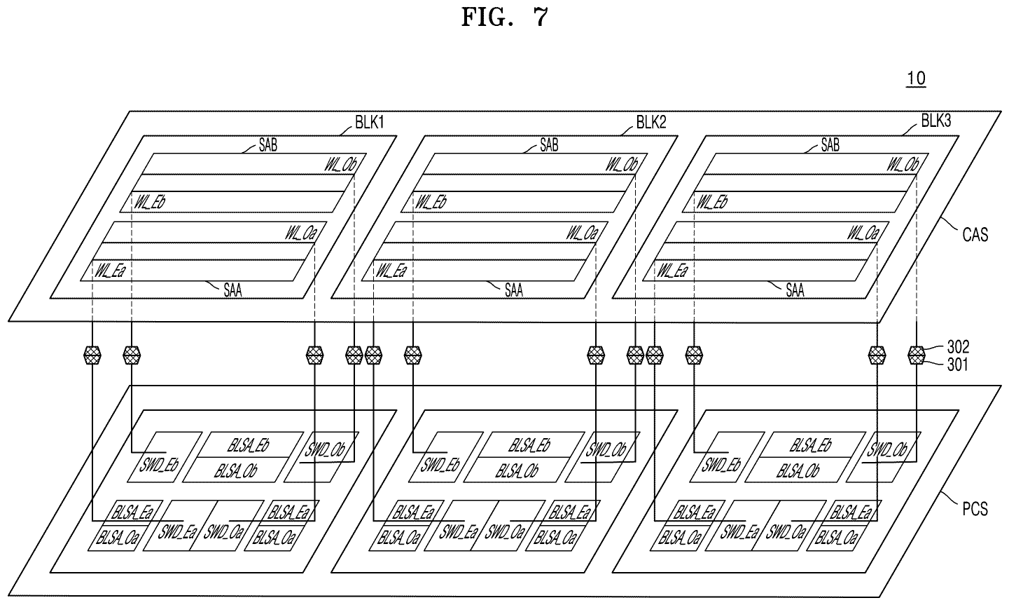

FIGS. 7 and 8 are diagrams for describing a memory device including sub-word line driver circuits and sense amplifier circuits of FIG. 5. FIG. 8 is a top plan view illustrating the memory device 10 of FIG. 7.

Referring to FIG. 7, the cell array structure CAS may include first to third memory blocks BLK1 to BLK3 each divided into the first sub-array SAA and the second sub-array SAB. The core peripheral circuit structure CPS may include, in an area overlapping each of the first to third memory blocks BLK1 to BLK3, the first even bit line sense amplifier circuit BLSA_Ea, the first even sub-word line driver circuit SWD_Ea, the first odd sub-word line driver circuit SWD_Oa, and the first odd bit line sense amplifier circuit BLSA_Oa corresponding to the first sub-array SAA, and may include the second even sub-word line driver circuit SWD_Eb, the second even bit line sense amplifier circuit BLSA_Eb, the second odd bit line sense amplifier circuit BLSA_Ob, and the second odd sub-word line driver circuit SWD_Ob corresponding to the second sub-array SAB.

The even word lines WL_Ea of the first sub-array SAA of each of the first to third memory blocks BLK1 to BLK3 may be electrically connected to the first even sub-word line driver circuit SWD_Ea through the bonding metal pads 302 and 301 at a first edge of the first sub-array SAA. The odd word lines WL_Oa of the first sub-array SAA of each of the first to third memory blocks BLK1 to BLK3 may be electrically connected to the first odd sub-word line driver circuit SWD_Oa through the bonding metal pads 302 and 301 at a second edge of the first sub-array SAA. The even word lines WL_Eb of the second sub-array SAB of each of the first to third memory blocks BLK1 to BLK3 may be electrically connected to the second even sub-word line driver circuit SWD_Eb through the bonding metal pads 302 and 301 at a first edge of the second sub-array SAB. The odd word lines WL_Ob of the second sub-array SAB of each of the first to third memory blocks BLK1 to BLK3 may be electrically connected to the second odd sub-word line driver circuit SWD_Ob through the bonding metal pads 302 and 301 at a second edge of the second sub-array SAB.

Referring to FIGS. 7 and 8, the even word lines WL_Ea and the odd word lines WL_Oa of the first sub-array SAA of each of the first to third memory blocks BLK1 to BLK3 may be electrically connected to the first even sub-word line driver circuit SWD_Ea and the first odd sub-word line driver circuit SWD_Oa located at the center of an area overlapping the first sub-array SAA. The even word lines WL_Eb and the odd word lines WL_Ob of the second sub-array SAB of each of the first to third memory blocks BLK1 to BLK3 may be electrically connected to the second even sub-word line driver circuit SWD_Eb and the second odd sub-word line driver circuit SWD_Ob located at both edges of an area overlapping the second sub-array SAB. That is, the sub-word line driver circuits SWD_Eb, SWD_Ea, SWD_Oa, and SWD_Ob of the first to third memory blocks BLK1 to BLK3 may be arranged in a zigzag or nonlinear manner (e.g., at least one of the sub-word line driver circuits SWD_Eb, SWD_Ea, SWD_Oa, and SWD_Ob are free from overlap in at least one of the horizontal directions D1 and D2). Also, the sense amplifier circuits BLSA_Ea, BLSA_Eb, BLSA_Ob, and BLSA_Oa of the first to third memory blocks BLK1 to BLK3 may also be arranged in a zigzag or nonlinear manner (e.g., at least one of the amplifier circuits BLSA_Ea, BLSA_Eb, BLSA_Ob, and BLSA_Oa are free from overlap in at least one of the horizontal directions D1 and D2).

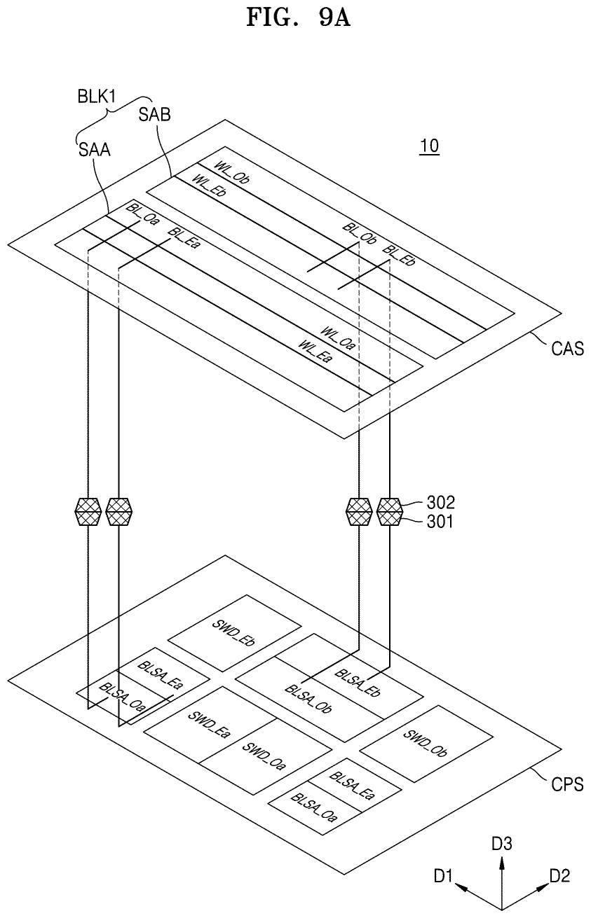

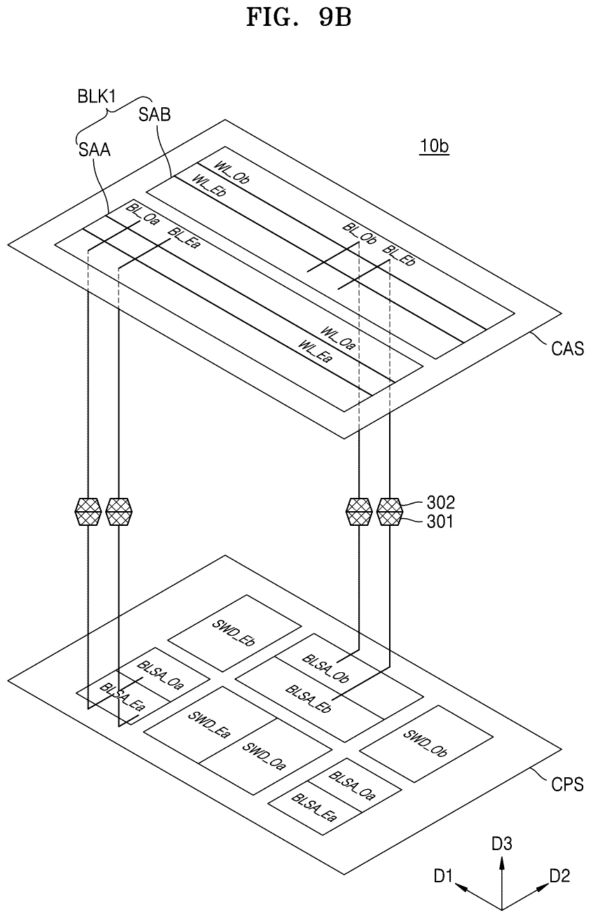

FIGS. 9A and 9B are diagrams for describing a memory device including sense amplifier circuits, according to embodiments.

Referring to FIGS. 5 and 9A, the even bit lines BL_Ea and the odd bit lines BL_Oa of the first sub-array SAA in the memory block BLK1 of the memory device 10 may be electrically connected to the first even bit line sense amplifier circuit BLSA_Ea and the first odd bit line sense amplifier circuit BLSA_Oa located at a first edge of an area overlapping the first sub-array SAA. The even bit lines BL_Eb and the odd bit lines BL_Ob of the second sub-array SAB may be electrically connected to the second even bit line sense amplifier circuit BLSA_Eb and the second odd bit line sense amplifier circuit BLSA_Ob located at the center of an area overlapping the second sub-array SAB.

Referring to FIG. 9B, the memory device 10b is different from the memory device 10 of FIG. 9A in that positions of the first even bit line sense amplifier circuit BLSA_Ea and the first odd bit line sense amplifier circuit BLSA_Oa are exchanged, and positions of the second even bit line sense amplifier circuit BLSA_Eb and the second odd bit line sense amplifier circuit BLSA_Ob are exchanged.

In FIGS. 9A and 9B, the even bit lines BL_Ea of the first sub-array SAA may be electrically connected to the first even bit line sense amplifier circuit BLSA_Ea through the bonding metal pads 302 and 301 at a lower edge of the first sub-array SAA. The odd bit lines BL_Oa of the first sub-array SAA may be electrically connected to the first odd bit line sense amplifier circuit BLSA_Oa through the bonding metal pads 302 and 301 at the lower edge of the first sub-array SAA. The even bit lines BL_Eb of the second sub-array SAB may be electrically connected to the second even bit line sense amplifier circuit BLSA_Eb through the bonding metal pads 302 and 301 at an upper edge of the second sub-array SAB. The odd bit lines BL_Ob of the second sub-array SAB may be electrically connected to the second odd bit line sense amplifier circuit BLSA_Ob through the bonding metal pads 302 and 301 at the upper edge of the second sub-array SAB.

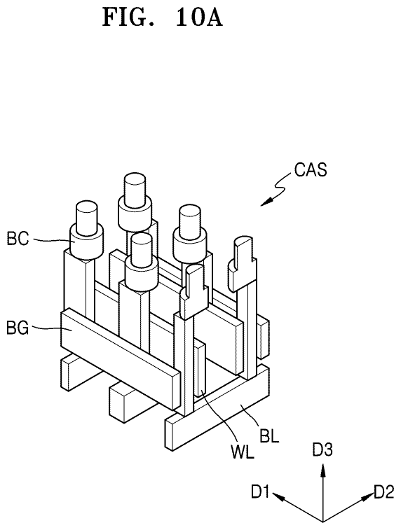

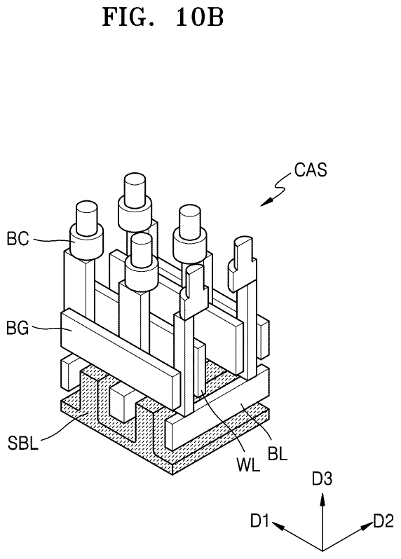

FIGS. 10A, 10B, and 11 are diagrams for describing a structure of a memory device, according to embodiments. FIGS. 10A and 10B are perspective views illustrating the cell array structure CAS of the memory device 10 of FIG. 5. The cell array structure CAS of FIG. 10B is a structure in which a shielding bit line SBL is located between the bit lines BL and under the bit lines BL in order to reduce coupling noise between the bit lines BL adjacent to each other in the cell array structure CAS of FIG. 10A. FIG. 11 is a cross-sectional view taken along a position (e.g., X1-X2 of FIG. 5) corresponding to a second direction D2.

Referring to FIGS. 10A, 10B, and 11 together, the core peripheral circuit structure CPS may include a lower substrate 310, an interlayer insulating layer 315, a plurality of circuit elements (e.g., 312a and 312b) formed on the lower substrate 310, first metal layers 314a and 314b respectively connected to the plurality of circuit elements (e.g., 312a and 312b), second metal layers 316a and 316b formed on the first metal layers 314a and 314b, and the bonding metal pad 301 formed on an uppermost metal layer of the core peripheral circuit structure CPS. In an embodiment, the first metal layers 314a and 314b may be formed of tungsten having relatively high resistance, the second metal layers 316a and 316b may be formed of copper having relatively low resistance, and the bonding metal pad 301 may be formed of copper. In another embodiment, the bonding metal pad 301 may be formed of aluminum (Al) or tungsten (W).

Although only the first metal layers 314a and 314b and the second metal layers 316a and 316b are illustrated and described in the specification, the present disclosure is not limited thereto, and one or more metal layers may be further formed on the second metal layers 316a and 316b. At least some of the one or more metal layers formed on the second metal layers 316a and 316b may be formed of aluminum or the like having lower resistance than copper of the second metal layers 316a and 316b. The interlayer insulating layer 315 may be located on the lower substrate 310 to cover or at least partially overlap the plurality of circuit elements (e.g., 312a and 312b), the first metal layers 314a and 314b, and the second metal layers 316a and 316b, and may include an insulating material such as silicon oxide or silicon nitride.

The plurality of circuit elements (e.g., 312a and 312b) may be connected to at least one of circuit elements constituting a peripheral circuit. For convenience of explanation, a first circuit element 312a represents transistors constituting the row decoder 25 or transistors constituting the sense amplifier 28, and a second circuit element 312b represents transistors constituting the control logic circuit 24.

In the memory device 10, the bit lines BL may be located on an upper substrate 320 to be spaced apart from each other in a first direction D1. The upper substrate 320 is named as an element corresponding to the lower substrate 310. According to some embodiments, the upper substrate 320 may be referred to as a plate or a conductive plate. The bit lines BL may be spaced apart from each other in the first direction D1 and may extend in the second direction D2 intersecting the first direction D1. Active patterns AP may be alternately located on the bit lines BL along the second direction D2. The active patterns AP may be arranged at certain intervals in the first direction D1. That is, the active patterns AP may be two-dimensionally arranged along the first direction D1 and the second direction D2 intersecting each other. In some embodiments, the plurality of word lines WL, the plurality of bit lines BL, and the plurality of active patterns AP constitute a plurality of vertical channel transistors.

Each of the active patterns AP may have a length in the first direction D1, may have a width in the second direction D2, and may have a height in the third direction D3 perpendicular to the upper substrate 320. The active patterns AP may have substantially uniform widths. Each of the active patterns AP may have a top surface and a bottom surface facing each other in the third direction D3. For example, the bottom surface of each of the active patterns AP may contact the bit line BL. Each of the active patterns AP may include a source region adjacent to the bit line BL, a drain region adjacent to a contact pattern BC, and a channel region between the source region and the drain region. The channel regions of the active patterns AP may be controlled by the word lines WL and the back gate electrodes BG during an operation of the memory device 10. The active patterns AP may be formed of, for example, single crystal silicon (Si), in order to improve leakage current characteristics during an operation of the memory device 10.

Back gate electrodes BG may be located on the bit lines BL to be arranged at certain intervals in the second direction D2. The back gate electrodes BG may extend in the first direction D1 across the bit lines BL. Each of the back gate electrodes BG may be located between the active patterns AP adjacent to each other in the second direction D2. A first active pattern 191 may be located on one side of each of the back gate electrodes BG, and a second active pattern 192 may be located on the other side of each of the back gate electrodes BG. The back gate electrodes BG may have a height less than a height of the active patterns AP in a vertical direction. A negative voltage may be applied to the back gate electrodes BG during an operation of the memory device 10, and a threshold voltage of the vertical channel transistor may increase. This means that as the vertical channel transistor is miniaturized, a threshold voltage decreases and leakage current characteristics are prevented or inhibited from being degraded.

A first insulating pattern 111 may be located between the active patterns AP adjacent to each other in the second direction D2. The first insulating pattern 111 may extend in the first direction D1 parallel to the back gate electrodes BG. A back gate insulating film 113 may be located between each back gate electrode BG and the active patterns AP and between the back gate electrode BG and the first insulating pattern 111. The back gate insulating film 113 may include vertical portions covering or at least partially overlapping both side surfaces of the back gate electrode BG and a horizontal portion connecting the vertical portions. The horizontal portion of the back gate insulating film 113 may be closer to the contact pattern BC than the bit line BL and may cover or at least partially overlap a bottom surface of the back gate electrode BG. A back gate capping pattern 115 may be located between the bit lines BL and the back gate electrode BG. The back gate capping pattern 115 may be formed of an insulating material, and a bottom surface of the back gate capping pattern 115 may contact the bit lines BL. The back gate capping pattern 115 may be located between the vertical portions of the back gate insulating film 113.

The word lines WL may be located on the bit lines BL, may extend in the first direction D1, and may be alternately arranged along the second direction D2. A first word line 181 from among the word lines WL may be located on one side of the first active pattern 191, and a second word line 182 from among the word lines WL may be located on the other side of the second active pattern 192. Portions of the first word lines 181 may be located between the first active patterns 191 adjacent to each other in the first direction D1, and portions of the second word lines 182 may be located between the second active patterns 192 adjacent to each other in the first direction D1.

The word lines WL may be vertically spaced apart from the bit lines BL and the contact patterns BC. The word lines WL may be located between the bit lines BL and the contact patterns BC in the vertical direction. The word lines WL adjacent to each other may have side walls facing each other. The word lines WL may have a height less than a height of the active patterns AP in the vertical direction. A height of the word lines WL may be equal to or greater than a height of the back gate electrodes BG in the third direction D3.

Gate insulating films 160 may be located between the word lines WL and the active patterns AP. The gate insulating films 160 may extend in the first direction D1 parallel to the word lines WL. The gate insulating film 160 may cover or at least partially overlap one side surface of the first active pattern 191 and the other side surface of the second active pattern 192. The gate insulating film 160 may have a substantially uniform thickness. A second insulating pattern 141 may be located between the gate insulating film 160 and the contact pads BC. For example, the second insulating pattern 141 may include silicon oxide. A first etching stop film 131 and a second etching stop film 133 may be located between the active patterns AP and the second insulating pattern 141.

The word lines WL on the gate insulating film 160 may be separated from each other by a third insulating pattern 151. The third insulating pattern 151 may be located between the word lines WL and may extend in the first direction D1. A first capping film 153 may be located between the third insulating pattern 151 and the word lines WL. The first capping film 153 may have a substantially uniform thickness. The third insulating pattern 151 may include a third vertical pattern 151A and a third horizontal pattern 151B.

The contact patterns BC may pass through or extend into a third etching stop film 210 and an interlayer insulating film 220 to be respectively connected to the active patterns AP. In other words, the contact patterns BC may be respectively connected to the drain regions of the active patterns AP. The contact patterns BC may have a lower width greater than an upper width. The contact pads BC adjacent to each other may be separated from each other by separation insulating patterns 230. Each of the contact patterns BC may have any of various planar shapes such as a circular shape, an elliptical shape, a rectangular shape, a square shape, a diamond shape, or a hexagonal shape. Land pads LP may be located on the contact patterns BC.

The separation insulating patterns 230 may be located between the landing pads LP. The landing pads LP may be arranged in a matrix form along the first direction D1 and the second direction D2 in a plan view. Top surfaces of the landing pads LP may be substantially coplanar with top surfaces of the separation insulating patterns 230. A fourth etching stop film 240 may be formed on the separation insulating patterns 230.

Data storage patterns DSP may be located on the landing pads LP. The data storage patterns DSP may be respectively electrically connected to the active patterns AP. The data storage patterns DSP may be arranged in a matrix form along the first direction D1 and the second direction D2. The data storage patterns DSP may completely or partially overlap the landing pads LP. The data storage patterns DSP may contact the whole or parts of the top surfaces of the landing pads LP. An upper insulating film 260 may be located on the data storage patterns DSP, and cell contact plugs PLG may pass through or extend into the upper insulating film 260 to be connected to a plate electrode 255.

In some embodiments, the data storage patterns DSP may be the cell capacitor CC (see FIG. 4), and may include a capacitor dielectric film 253 located between storage electrodes 251 and the plate electrode 255. In this case, the storage electrode 251 may directly contact the landing pad LP, and the storage electrode 251 may have any of various planar shapes such as a circular shape, an elliptical shape, a rectangular shape, a square shape, a diamond shape, or a hexagonal shape.

In some embodiments, the data storage patterns DSP may be variable resistance patterns that may be switched between two resistance states by an electrical pulse applied to a memory element. For example, the data storage patterns DSP may include, but is not limited to, a phase-change material whose crystal state changes according to the amount of current, a perovskite compound, transition metal oxide, a magnetic material, a ferromagnetic material, and an antiferromagnetic material. According to a material film of the data storage patterns DSP, the memory device 10 may be implemented as a resistive memory such as a phase-change RAM (PRAM), a magnetic RAM (MRAM), or a resistive RAM (RRAM)

The shielding bit line SBL may be located between the bit lines BL and under the bit lines BL. The shielding bit line SBL may reduce coupling noise between the bit lines BL adjacent to each other. For example, the shielding bit line SBL may be a shielding structure formed of a conductive material. First line insulating layers 173 may be spaced apart from each other in the first direction D1 and may extend in the second direction D2. The first line insulating layers 173 may contact facing side walls of the bit lines BL adjacent to each other and may be separated from each other in the first direction D1. A second line insulating layer 325 may at least partially surround a bottom surface and a side surface of the shielding bit line SBL and may at least partially fill a space between the shielding bit lines SBL.

A through-electrode 322 may pass through or extend into the upper substrate 320 to contact a metal layer 318b, and may extend long in the third direction D3 to the bonding metal pad 302 formed on the uppermost metal layer of the core peripheral circuit structure CPS. Although only the metal layers 318a and 318b are illustrated and described in the present embodiments, the present disclosure is not limited thereto, and one or more metal layers may be further formed on the metal layers 318a and 318b. The shielding bit line SBL may be electrically connected to the second circuit element 312b of the control logic circuit 24 through the bonding metal pad 302 of the cell array structure CAS and the bonding metal pad 301 of the core peripheral circuit structure CPS. The shielding bit line SBL may be controlled by the control logic circuit 24.

In some embodiments, the bonding metal pad 302 of the cell array structure CAS and the bonding metal pad 301 of the core peripheral circuit structure CPS may be connected to each other through an electrical or physical bonding method. When the bonding metal pads 301 and 302 are formed of copper (Cu), the bonding method may be a Cu—Cu bonding method. In another example, the bonding metal pads 301 and 302 may be formed of aluminum (Al) or tungsten (W).

The metal layer 318a of the cell array structure CAS may be electrically or physically connected to each of the word lines WL and may contact the bonding metal pad 301. Each of the word lines WL may be electrically connected to the first circuit element 312a of the row decoder 25 through the bonding metal pad 302 of the cell array structure CAS and the bonding metal pad 301 of the core peripheral circuit structure CPS. The metal layer 318b of the cell array structure CAS may be electrically or physically connected to each of the bit lines BL and may contact the bonding metal pad 301. Each of the bit lines BL may be electrically connected to the second circuit element 312b of the sense amplifier 28 through the bonding metal pad 302 of the cell array structure CAS and the bonding metal pad 301 of the core peripheral circuit structure CPS.

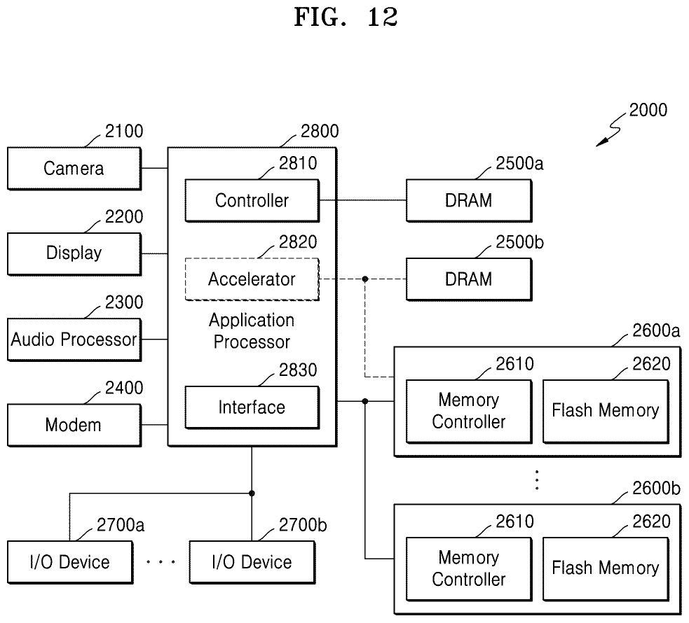

FIG. 12 is a block diagram illustrating a system 2000 for describing an electronic device including a memory device, according to embodiments.

Referring to FIG. 12, the system 2000 may include a camera 2100, a display 2200, an audio processor 2300, a modem 2400, DRAMs 2500a and 2500b, flash memories 2600a and 2600b, I/O devices 2700a and 2700b, and an application processor (hereinafter, referred to as AP) 2800. The system 2000 may be implemented as a laptop computer, a mobile phone, a smartphone, a table personal computer (PC), a wearable device, a healthcare device, or an Internet of things (IOT) device. Also, the system 2000 may be implemented as a server or a PC.

The camera 2100 may capture a still image or a video according to a user's control, and may store the captured image/video data or transmit the captured image/video data to the display 2200. The audio processor 2300 may process audio data included in content of a network or the flash memories 2600a and 2600b. The modem 2400 may modulate and transmit a signal for wired/wireless data transmission/reception and may demodulate the modulated signal to recover the modulated signal into an original signal at a receiver side. The I/O devices 2700a and 2700b may include devices having digital input/output functions such as a universal serial bus (USB) or a storage, a digital camera, a secure digital (SD) card, a digital versatile disc (DVD), a network adapter, and a touchscreen.

The AP 2800 may control an overall operation of the system 2000. The AP 2800 may include a control block 2810, an accelerator block or accelerator chip 2820, and an interface block 2830. The AP 2800 may control the display 2200 to display part of content stored in the flash memories 2600a and 2600b to be displayed on the display 2200. When the AP 2800 receives a user input through the I/O devices 2700a and 2700b, the AP 2800 may perform a control operation corresponding to the user input. The AP 2800 may include an accelerator block that is a dedicated circuit for artificial intelligence (AI) data operations, or may include the accelerator chip 2820 separate from the AP 2800. The DRAM 2500b may be additionally mounted on the accelerator block or accelerator chip 2820. The accelerator is a functional block that specializes in performing a specific function of the AP 2800, and the accelerator may include a graphics processing unit (GPU) that is a functional block that specializes in performing graphic data processing, a neural processing unit (NPU) that is a functional block that specializes in performing AI calculation and inference, and a data processing unit (DPU) that is a block that specializes in performing data transmission. In an embodiment, an image captured by the user through the camera 2100 may be signal-processed and stored in the DRAM 2500b, and the accelerator block or accelerator chip 2820 may perform an AI data operation for recognizing data by using data stored in the DRAM 2500b and a function used for inference.

The system 2000 may include a plurality of DRAMs 2500a and 2500b. The AP 2800 may control the DRAMs 2500a and 2500b by setting a command and a mode register MRS suitable for the joint electron device engineering council (JEDEC) standard, or may perform communication by setting a DRAM interface protocol in order to use company-specific functions such as a low voltage/a high speed/reliability and cyclic redundancy check (CRC)/error correction code (ECC) functions. For example, the AP 2800 may communicate with the DRAM 2500a with an interface suitable for the JEDEC standard such as LPDDR4 or LPDDR5, and the accelerator block or accelerator chip 2820 may perform communication by setting a new DRAM interface protocol in order to control the DRAM 2500b for an accelerator having a higher bandwidth than that of the DRAM 2500a.

Although only the DRAMs 2500a and 2500b are illustrated in FIG. 12, the present disclosure is not limited thereto, and as long as a bandwidth, a response speed, and voltage conditions of the AP 2800 or the accelerator chip 2820 are satisfied, any memory such as PRAM, static RAM (SRAM), MRAM, RRAM, ferroelectric RAM (FRAM), or hybrid RAM may be used. The DRAMs 2500a and 2500b may have latencies and bandwidths lower than those of the I/O devices 2700a and 2700b or the flash memories 2600a and 2600b. The DRAMs 2500a and 2500b may be initialized at a power-on time of the system 2000, and an operating system and application data may be loaded and the DRAMs 2500a and 2500b may be used as a temporary storage of the operating system and the application data or may be used as an execution space for various software code.

Addition/subtraction/multiplication/division, a vector operation, an address operation, or a fast Fourier transform (FFT) operation may be performed in the DRAMs 2500a and 2500b. Also, a function used for inference may be performed in the DRAMs 2500a and 2500b. Here, the inference may be performed in a deep learning algorithm using an artificial neural network. The deep learning algorithm may include a training operation of training a model through various data and an inference operation of recognizing data by using the trained model.

The system 2000 may include a plurality of storages or a plurality of flash memories 2600a and 2600b having capacity greater than that of the DRAMs 2500a and 2500b. The accelerator block or accelerator chip 2820 may perform a training operation and an AI data operation by using the flash memories 2600a and 2600b. In an embodiment, the flash memories 2600a and 2600b may include a memory controller 2610 and a flash memory device 2620, and may more efficiently perform a training operation and an inference AI data operation performed by the AP 2800 and/or the accelerator chip 2820 by using an operation device provided in the memory controller 2610. The flash memories 2600a and 2600b may store a photograph taken by the camera 2100 or may store data received through a data network. For example, the flash memories 2600a and 2600b may store augmented reality/virtual reality, high definition (HD), or ultra high definition (UHD) content.

In the system 2000, the DRAMs 2500a and 2500b may include the memory device described with reference to FIGS. 1 to 11. A memory device may include a core peripheral circuit structure including a first bonding metal pad, and a cell array structure located on the core peripheral circuit structure to vertically overlap the core peripheral circuit structure and including a second bonding metal pad contacting the first bonding metal pad. The cell array structure may include a memory cell array area including a plurality of memory blocks including a plurality of word lines and a plurality of bit lines, and each of the plurality of memory blocks may include a first sub-array and a second sub-array. The core peripheral circuit structure may include a row decoder electrically connected to the first bonding metal pad and the second bonding metal pad connected to each of the plurality of word lines of the plurality of memory blocks and a sense amplifier circuit electrically connected to the first bonding metal pad and the second bonding metal pad connected to each of the plurality of bit lines of the plurality of memory blocks, and the row decoder may include a main word line driver circuit commonly connected to the first sub-array and the second sub-array and a sub-word line driver circuit connected to each of the first sub-array and the second sub-array. In an area of the core peripheral circuit structure overlapping the first sub-array, a first even bit line sense amplifier circuit electrically connected to each of even bit lines of the first sub-array, a first even sub-word line driver circuit electrically connected to even word lines of the first sub-array, a first odd sub-word line driver circuit electrically connected to odd word lines of the first sub-array, and a first odd bit line sense amplifier circuit electrically connected to each of odd bit lines of the first sub-array may be aligned. In an area of the core peripheral circuit structure overlapping the second sub-array, a second even sub-word line driver circuit electrically connected to even word lines of the second sub-array, a second even bit line sense amplifier circuit electrically connected to each of even bit lines of the second sub-array, a second odd bit line sense amplifier circuit electrically connected to each of odd bit lines of the second subarray, and a second odd sub-word line driver circuit electrically connected to odd word lines of the second sub-array may be aligned. A signal setup speed of word lines and bit lines may be improved and high-speed operation performance may be improved, through memory devices in which sub-word line driver circuits and/or sense amplifier circuits corresponding to a plurality of memory blocks are arranged in a zigzag. The memory devices may be applied to high-speed communication devices and systems.

As described above, embodiments have been illustrated in the drawings and described in the specification. While embodiments have been described by using specific terms, the terms have merely been used to explain the present disclosure and should not be construed as limiting the scope of the present disclosure defined by the claims. Hence, it will be understood by one of ordinary skill in the art that various modifications and other equivalent embodiments may be made therefrom. Accordingly, the technical scope of the present disclosure should be defined by the following claims.

While the present disclosure has been particularly shown and described with reference to embodiments thereof, it will be understood that various changes in form and details may be made therein without departing from the spirit and scope of the following claims.

What is claimed is:

1. A memory device comprising:
a core peripheral circuit structure comprising a first bonding metal pad; and
a cell array structure on the core peripheral circuit structure, the cell array structure comprising a second bonding metal pad contacting the first bonding metal pad,
wherein the cell array structure comprises a memory cell array area comprising a plurality of memory blocks that comprise a plurality of word lines, each of the plurality of memory blocks comprising a first sub-array and a second sub-array, and
wherein the core peripheral circuit structure comprises a row decoder comprising a sub-word line driver circuit, that is electrically connected to the first bonding metal pad and the second bonding metal pad and is electrically connected to each of the plurality of word lines of the plurality of memory blocks, the sub-word line driver circuit comprising a first even sub-word line driver circuit, a second even sub-word line driver circuit, a first odd sub-word line driver circuit, and a second odd sub-word line driver circuit,
wherein a first area of the core peripheral circuit structure at least partially overlaps the first sub-array in a first direction, the first area of the core peripheral circuit structure comprising the first even sub-word line driver circuit that is electrically connected to even word lines of the first sub-array and the first odd sub-word line driver circuit that is electrically connected to odd word lines of the first sub-array, and
wherein a second area of the core peripheral circuit structure at least partially overlaps the second sub-array in the first direction, the second area of the core peripheral circuit structure comprising the second even sub-word line driver circuit that is electrically connected to even word lines of the second sub-array and the second odd sub-word line driver circuit that is electrically connected to odd word lines of the second sub-array.

2. The memory device of claim 1, wherein the row decoder comprises:
a main word line driver circuit electrically connected to the first sub-array and the second sub-array,
wherein the sub-word line driver circuit is electrically connected to each of the first sub-array and the second sub-array.

3. The memory device of claim 1, wherein:
the first area of the core peripheral circuit structure comprises a first even bit line sense amplifier circuit electrically connected to even bit lines of the first sub-array and a first odd bit line sense amplifier circuit electrically connected to odd bit lines of the first sub-array; and
the second area of the core peripheral circuit structure comprises a second even bit line sense amplifier circuit electrically connected to even bit lines of the second sub-array and a second odd bit line sense amplifier circuit electrically connected to odd bit lines of the second sub-array.

4. The memory device of claim 3, wherein:
in the first area of the core peripheral circuit structure, the first even and odd bit line sense amplifier circuits, the first even sub-word line driver circuit, the first odd sub-word line driver circuit, and the first even and odd bit line sense amplifier circuits at least partially overlap each other in a second direction that is perpendicular to the first direction,
in the second area of the core peripheral circuit structure, the second even sub-word line driver circuit, the second even and odd bit line sense amplifier circuits, and the second odd sub-word line driver circuit at least partially overlap each other in the second direction, and
at least one of the first even sub-word line driver circuit, the second even sub-word line driver circuit, the first odd sub-word line driver circuit, and the second odd sub-word line driver circuit are free from overlap in the second direction.

5. The memory device of claim 4, wherein the first even and odd bit line sense amplifier circuits and the second even and odd bit line sense amplifier circuits at least partially overlap each other in a third direction that intersects the second direction and is perpendicular to the first direction.

6. The memory device of claim 3, wherein,
in the first area of the core peripheral circuit structure, the first even and odd bit line sense amplifier circuits, the first odd sub-word line driver circuit, the first even sub-word line driver circuit, and the first even and odd bit line sense amplifier circuits at least partially overlap each other in a second direction that is perpendicular to the first direction,
in the second area of the core peripheral circuit structure, the second odd sub-word line driver circuit, the second even and odd bit line sense amplifier circuits, and the second even sub-word line driver circuit at least partially overlap each other in the second direction, and
at least one of the first even sub-word line driver circuit, the second even sub-word line driver circuit, the first odd sub-word line driver circuit, and the second odd sub-word line driver circuit are free from overlap in the second direction.

7. The memory device of claim 6, wherein the first even and odd bit line sense amplifier circuits and the second even and odd bit line sense amplifier circuits at least partially overlap each other in a third direction that intersects the second direction and is perpendicular to the first direction.

8. The memory device of claim 7, further comprising a plurality of bit lines that comprise the even bit lines of the first sub-array, the odd bit lines of the first sub-array, the even bit lines of the second sub-array, and the odd bit lines of the second sub-array, wherein the memory cell array area comprises a shielding bit line between the plurality of bit lines and on lower surfaces of the plurality of bit lines.

9. The memory device of claim 1, wherein the plurality of word lines extend in a second direction that is perpendicular to the first direction, wherein the memory cell array area comprises a plurality of bit lines that extend in a third direction that intersects the second direction, wherein the memory cell array area comprises a plurality of cell structures comprising a plurality of vertical channel transistor structures respectively on the plurality of bit lines, and wherein the memory cell array area comprises a plurality of capacitor structures respectively electrically connected to the plurality of vertical channel transistor structures.

10. A memory device comprising:
a core peripheral circuit structure comprising a first bonding metal pad; and
a cell array structure on the core peripheral circuit structure, the cell array structure comprising a second bonding metal pad contacting the first bonding metal pad,
wherein the cell array structure comprises a memory cell array area comprising a plurality of memory blocks that comprise a plurality of bit lines, each of the plurality of memory blocks comprising a first sub-array and a second sub-array, and
wherein the core peripheral circuit structure comprises a sense amplifier circuit electrically connected to the first bonding metal pad and the second bonding metal pad and is electrically connected to each of the plurality of bit lines, the sense amplifier circuit comprising a first even bit line sense amplifier circuit, a second even bit line sense amplifier circuit, a first odd bit line sense amplifier circuit, and a second odd bit line sense amplifier circuit,
wherein a first area of the core peripheral circuit structure at least partially overlaps the first sub-array in a first direction, the first area of the core peripheral circuit structure comprising the first even bit line sense amplifier circuit that is electrically connected to each of even bit lines of the first sub-array and a first odd bit line sense amplifier circuit electrically connected to each of odd bit lines of the first sub-array, and
wherein a second area of the core peripheral circuit structure at least partially overlaps the second sub-array in the first direction, the second area of the core peripheral circuit structure comprising the second even bit line sense amplifier circuit that is electrically connected to each of even bit lines of the second sub-array and a second odd bit line sense amplifier circuit electrically connected to each of odd bit lines of the second sub-array.

11. The memory device of claim 10, wherein:
the first area of the core peripheral circuit structure comprises a first even sub-word line driver circuit electrically connected to even word lines of the first sub-array and a first odd sub-word line driver circuit electrically connected to odd word lines of the first sub-array; and
the second area of the core peripheral circuit structure comprises a second even sub-word line driver circuit electrically connected to even word lines of the second sub-array and a second odd sub-word line driver circuit electrically connected to odd word lines of the second sub-array.

12. The memory device of claim 11, wherein:
in the first area of the core peripheral circuit structure, the first even and odd bit line sense amplifier circuits, the first even sub-word line driver circuit, the first odd sub-word line driver circuit, and the first even and odd bit line sense amplifier circuits at least partially overlap each other in a second direction that is perpendicular to the first direction,
in the second area of the core peripheral circuit structure, the second even sub-word line driver circuit, the second even and odd bit line sense amplifier circuits, and the second odd sub-word line driver circuit are at least partially overlap each other in the second direction, and
at least one of the first even bit line sense amplifier circuit, the second even bit line sense amplifier circuit, the first odd bit line sense amplifier circuit, and the second odd bit line sense amplifier circuit are free from overlap in the second direction.

13. The memory device of claim 12, wherein the first even and odd bit line sense amplifier circuits and the second even and odd bit line sense amplifier circuits at least partially overlap each other in a third direction that intersects the second direction and is perpendicular to the first direction.

14. The memory device of claim 11, wherein,
in the first area of the core peripheral circuit structure, the first even and odd bit line sense amplifier circuits, the first even sub-word line driver circuit, the first odd sub-word line driver circuit, and the first even and odd bit line sense amplifier circuits at least partially overlap each other in a second direction that is perpendicular to the first direction,
in the second area of the core peripheral circuit structure, the second even sub-word line driver circuit, the second even and odd bit line sense amplifier circuits, and the second odd sub-word line driver circuit at least partially overlap each other in the second direction, and
at least one of the first even bit line sense amplifier circuit, the second even bit line sense amplifier circuit, the first odd bit line sense amplifier circuit, and the second odd bit line sense amplifier circuit are free from overlap in the second direction.

15. The memory device of claim 14, wherein the first even and odd bit line sense amplifier circuits and the second even and odd bit line sense amplifier circuits at least partially overlap each other in a third direction that intersects the second direction and is perpendicular to the first direction.

16. The memory device of claim 15, wherein the memory cell array area comprises a shielding bit line between the plurality of bit lines and on lower surfaces of the plurality of bit lines.

17. The memory device of claim 10, wherein the memory cell array area comprises a plurality of word lines extending in a second direction that is perpendicular to the first direction, the plurality of bit lines extending in a third direction that intersects the second direction, wherein the memory cell array area comprises a plurality of cell structures comprising a plurality of vertical channel transistor structures respectively on the plurality of bit lines, and wherein the memory cell array area comprises a plurality of capacitor structures respectively electrically connected to the plurality of vertical channel transistor structures.

18. A memory device comprising:
a core peripheral circuit structure comprising a first bonding metal pad; and
a cell array structure on the core peripheral circuit structure, the cell array structure comprising a second bonding metal pad contacting the first bonding metal pad,
wherein the cell array structure comprises a memory cell array area comprising a plurality of memory blocks that comprise a plurality of word lines and a plurality of bit lines, each of the plurality of memory blocks comprising a first sub-array and a second sub-array, and
the core peripheral circuit structure comprises:
a row decoder electrically that is electrically connected to the first bonding metal pad and the second bonding metal pad and is electrically connected to each of the plurality of word lines of the plurality of memory blocks, the row decoder comprising a sub-word line driver circuit of the row decoder connected to each of the first sub-array and the second sub-array, the sub-word line driver circuit comprising a first even sub-word line driver circuit, a second even sub-word line driver circuit, a first odd sub-word line driver circuit, and a second odd sub-word line driver circuit; and
a sense amplifier circuit that is electrically connected to the first bonding metal pad and the second bonding metal pad and is electrically connected to each of the plurality of bit lines of the plurality of memory blocks, the sense amplifier circuit comprising a first even bit line sense amplifier circuit, a second even bit line sense amplifier circuit, a first odd bit line sense amplifier circuit, and a second odd bit line sense amplifier circuit,
wherein a first area of the core peripheral circuit structure at least partially overlaps the first sub-array in a first direction, the first area of the core peripheral circuit structure comprising the first even bit line sense amplifier circuit electrically connected to each of even bit lines of the first sub-array, the first even sub-word line driver circuit electrically connected to even word lines of the first sub-array, the first odd sub-word line driver circuit electrically connected to odd word lines of the first sub-array, and the first odd bit line sense amplifier circuit electrically connected to each of odd bit lines of the first sub-array, and
wherein a second area of the core peripheral circuit structure at least partially overlaps the second sub-array in the first direction, the second area of the core peripheral circuit structure comprising the second even sub-word line driver circuit electrically connected to even word lines of the second sub-array, the second even bit line sense amplifier circuit electrically connected to each of even bit lines of the second sub-array, the second odd bit line sense amplifier circuit electrically connected to each of odd bit lines of the second sub-array, and the second odd sub-word line driver circuit electrically connected to odd word lines of the second sub-array.

19. The memory device of claim 18, wherein the row decoder comprises:
a main word line driver circuit electrically connected to the first sub-array and the second sub-array,
wherein the sub-word line driver circuit is electrically connected to each of the first sub-array and the second sub-array.

20. The memory device of claim 18, wherein:
at least one of the first even sub-word line driver circuit, the second even sub-word line driver circuit, the first odd sub-word line driver circuit, and the second odd sub-word line driver circuit are free from overlap in a second direction that is perpendicular to the first direction, and
at least one of the first even bit line sense amplifier circuit, the second even bit line sense amplifier circuit, the first odd bit line sense amplifier circuit, and the second odd bit line sense amplifier circuit are free from overlap in the second direction.
